(19) United States
(12) Patent Application Publication
(10) Pub. No.: US 2026/0231717 A1
(43) Pub. Date: Aug. 6, 2026

(54) TEMPERATURE CONTROL SYSTEM, TEMPERATURE CONTROL METHOD, METHOD OF MANUFACTURING SEMICONDUCTOR DEVICE AND SUBSTRATE PROCESSING APPARATUS

(71) Applicant: Kokusai Electric Corporation, Tokyo (JP)

(72) Inventors: Hideyuki NISHIMOTO, Toyama (JP); Yusaku OKAJIMA, Toyama (JP); Shintaro KOJIMA, Toyama (JP)

(21) Appl. No.: 19/636,478

(22) Filed: Apr. 1, 2026

Related U.S. Application Data
(63) Continuation of application No. PCT/JP2024/033338, filed on Sep. 18, 2024.

(30) Foreign Application Priority Data
Jan. 23, 2024 (JP) 2024-008228

(51) Int. Cl. H10P 72/00; H05B 1/02

(52) U.S. Cl. CPC H10P 72/0434; H05B 1/0233; H10P 72/0602

(57) ABSTRACT

It is possible to suppress an increase in a wire temperature of an auxiliary heater and to ensure the life of the auxiliary heater. There is provided a technique that includes: a first heater divided into a plurality of zones and configured to heat a process vessel in which a substrate is arranged; a second heater configured to assist in heating a specific zone among the plurality of zones by the first heater; a temperature sensor configured to detect a temperature of the second heater; and a controller configured to be capable of controlling an inner temperature of the process vessel to a target temperature by limiting an output of the second heater when the temperature detected by the temperature sensor is equal to or higher than a predetermined temperature lower than the target temperature.

### CROSS REFERENCE TO RELATED APPLICATIONS

This application is a bypass continuation application of PCT International Application No. PCT/JP2024/033338, filed on September 18, 2024, in the WIPO, the international application being based upon and claiming the benefit of priority from Japanese Patent Application No. 2024-008228, filed on January 23, 2024, in the Japanese Patent Office, the entire contents of which are hereby incorporated by reference.

### TECHNICAL FIELD

The present disclosure relates to a temperature control system, a temperature control method, a method of manufacturing a semiconductor device and a substrate processing apparatus.

### BACKGROUND

### Related Art

According to some related arts, as a part of a manufacturing process of a semiconductor device, a predetermined process may be performed on a wafer (hereinafter, also referred to as a “substrate”). In such a process, a temperature of a process chamber may be controlled using an auxiliary heater capable of assisting in heating a specific zone.

### SUMMARY

According to the present disclosure, there is provided a technique capable of suppressing an increase in a wire temperature of an auxiliary heater and ensuring the life of the auxiliary heater.

According to the embodiments of the present disclosure, there is provided a technique that includes: a first heater divided into a plurality of zones and configured to heat a process vessel in which a substrate is arranged; a second heater configured to assist in heating a specific zone among the plurality of zones by the first heater; a temperature sensor configured to detect a temperature of the second heater; and a controller configured to be capable of controlling an inner temperature of the process vessel to a target temperature by limiting an output of the second heater when the temperature detected by the temperature sensor is equal to or higher than a predetermined temperature lower than the target temperature.

### BRIEF DESCRIPTION OF THE DRAWINGS

FIG. 1 is a diagram schematically illustrating a process furnace of a substrate processing apparatus according to one or more embodiments of the present disclosure.

FIG. 2 is a diagram schematically illustrating a cross-section of a subsidiary heater and its surrounding area of the substrate processing apparatus according to the embodiments of the present disclosure, when viewed from front.

FIG. 3A is a diagram schematically illustrating the subsidiary heater of the substrate processing apparatus according to the embodiments of the present disclosure, when viewed from above.

FIG. 3B is a diagram schematically illustrating a partial vertical cross-section of the subsidiary heater shown in FIG. 3A.

FIG. 4 is a block diagram schematically illustrating a configuration of a controller and its related components of the substrate processing apparatus according to the embodiments of the present disclosure.

FIG. 5A is a diagram schematically illustrating a first mode of a temperature control by a temperature control system according to the embodiments of the present disclosure.

FIG. 5B is a diagram schematically illustrating a second mode of the temperature control by the temperature control system according to the embodiments of the present disclosure.

FIG. 5C is a diagram schematically illustrating a third mode of the temperature control by the temperature control system according to the embodiments of the present disclosure.

FIG. 6 is a block diagram schematically illustrating the temperature control system of the substrate processing apparatus according to the embodiments of the present disclosure.

FIG. 7A is a flow chart schematically illustrating a substrate processing sequence performed by the substrate processing apparatus according to the embodiments of the present disclosure.

FIG. 7B is a graph schematically illustrating a temperature at each step of the substrate processing sequence performed by the substrate processing apparatus according to the embodiments of the present disclosure.

### DETAILED DESCRIPTION

### Configuration of Substrate Processing Apparatus

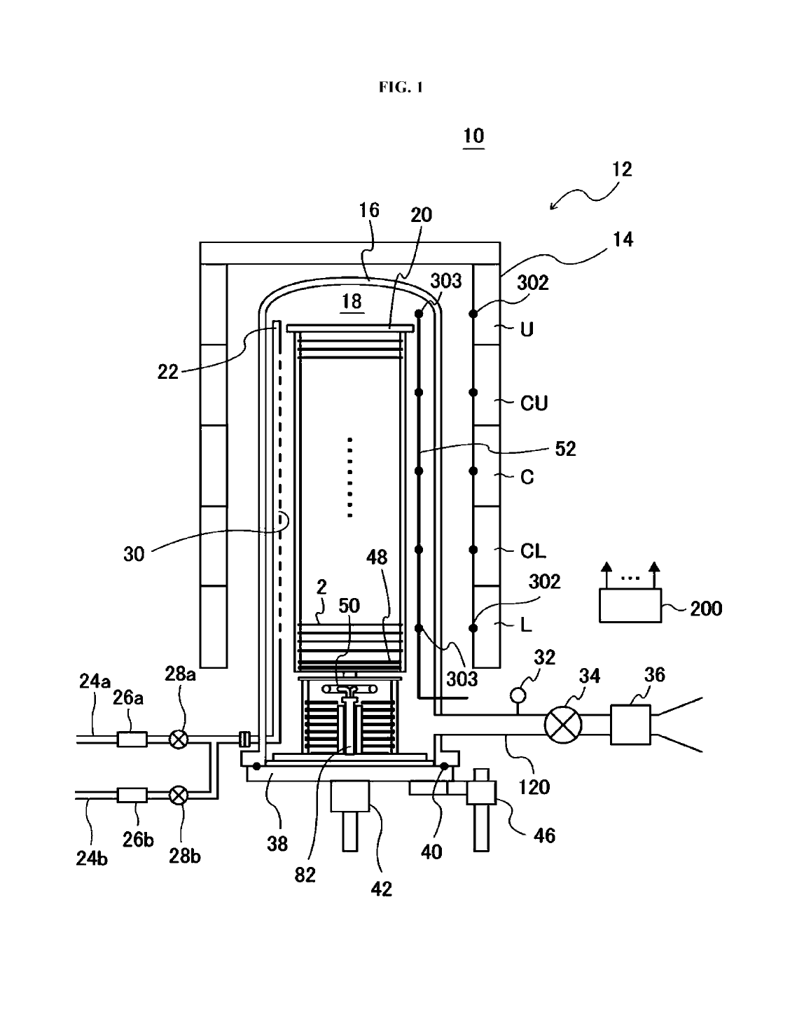

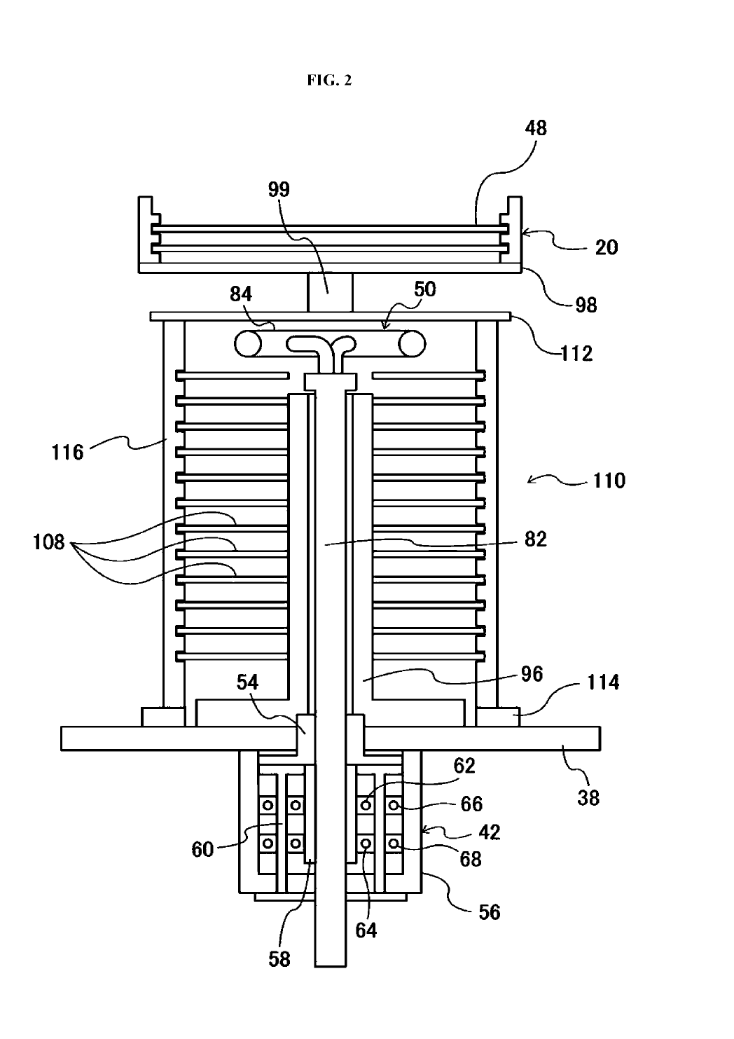

Hereinafter, one or more embodiments (also simply referred to as “embodiments”) according to the technique of the present disclosure will be described mainly with reference to FIGS. 1 to 7. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary.

As shown in FIG. 1, a substrate processing apparatus 10 according to the present embodiments is configured as a processing apparatus (also referred to as a “batch type processing apparatus”) capable of performing a process in a method of manufacturing an IC (integrated circuit). A process furnace 12 of the substrate processing apparatus 10 is provided with a heater 14 serving as a first heater (which is a heating apparatus or a heating structure). The heater 14 is of a cylindrical shape, and is installed in a vertical direction.

A reaction tube 16 constituting a reaction vessel (also referred to as a “process vessel”) is provided in an inner side of the heater 14 to be aligned in a manner concentric with the heater 14. For example, the reaction tube 16 is made of a heat resistant material such as quartz (SiO₂) and silicon carbide (SiC). For example, the reaction tube 16 is of a cylindrical shape with a closed upper end and an open lower end. A process chamber 18 is provided in a hollow cylindrical portion of the reaction tube 16. The process chamber 18 is configured to be capable of accommodating a plurality of wafers 2 in a horizontal orientation to be vertically arranged (aligned) in a multistage manner by a boat 20 described later. Hereinafter, each of the plurality of wafers 2 may also be simply referred to as a “wafer 2” serving as a substrate.

A nozzle 22 is installed in the process chamber 18 so as to penetrate a lower portion of the reaction tube 16. For example, the nozzle 22 is made of a heat resistant material such as quartz and SiC. A gas supply pipe 24a is connected to the nozzle 22. A mass flow controller (MFC) 26a serving as a flow rate controller (flow rate control structure) and a valve 28a serving as an opening/closing valve are sequentially installed at the gas supply pipe 24a in this order from an upstream side to a downstream side of the gas supply pipe 24a in a gas flow direction. A gas supply pipe 24b through which an inert gas is supplied is connected to the gas supply pipe 24a at a downstream side of the valve 28a. An MFC 26b and a valve 28b are sequentially installed at the gas supply pipe 24b in this order from an upstream side to a downstream side of the gas supply pipe 24b in the gas flow direction. A process gas supplier (which is a process gas supply structure or a process gas supply system) is constituted mainly by the gas supply pipe 24a, the MFC 26a and the valve 28a. An inert gas supplier (which is an inert gas supply structure or an inert gas supply system) is constituted mainly by the gas supply pipe 24b, the MFC 26b and the valve 28b.

The nozzle 22 is installed in an annular space between an inner wall of the reaction tube 16 and the wafers 2, and extends from a lower portion to an upper portion of the inner wall of the reaction tube 16 along an arrangement direction of the wafers 2. That is, the nozzle 22 is installed in a region that is located beside and horizontally surrounds a wafer arrangement region in which the wafers 2 are arranged along the wafer arrangement region. The nozzle 22 is configured as an L-shaped nozzle. A horizontal portion of the nozzle 22 is installed through a lower side wall of the reaction tube 16. A vertical portion of the nozzle 22 extends from a lower end toward an upper end of the wafer arrangement region. A plurality of gas supply holes 30 through which a gas is supplied are provided at a side surface of the nozzle 22. The gas supply holes 30 are open toward a center of the reaction tube 16 such that the gas can be supplied toward the wafers 2. The gas supply holes 30 are provided from the lower portion to the upper portion of the reaction tube 16. An opening area of each of the gas supply holes 30 is the same, and each of the gas supply holes 30 is provided at the same pitch.

However, the process furnace 12 according to the present embodiments is not limited to the example described above. For example, a manifold made of a metal material and configured to support the reaction tube 16 may be installed under the reaction tube 16, and a nozzle may be installed so as to penetrate a side wall of the manifold. In such a case, an exhaust pipe 120 described later may be provided at the manifold. Even when the manifold is provided, the exhaust pipe 120 may be installed at the lower portion of the reaction tube 16 instead of the manifold. In a manner described above, a furnace opening of the process furnace 12 may be defined by a structure made of a metal material, and components such as the nozzle 22 may be installed at the structure made of the metal material. For example, a plurality of nozzles including the nozzle 22 may be provided.

The exhaust pipe 120 through which an atmosphere (inner atmosphere) of the process chamber 18 is exhausted is installed at the reaction tube 16. A vacuum pump 36 serving as a vacuum exhaust apparatus is connected to the exhaust pipe 120 through a pressure sensor 32 and an APC (Automatic Pressure Controller) valve 34. The pressure sensor 32 serves as a pressure detector (pressure detection structure) configured to detect a pressure (inner pressure) of the process chamber 18, and the APC valve 34 serves as a pressure regulator (pressure adjusting structure). With the vacuum pump 36 in operation, the APC valve 34 may be opened or closed to perform a vacuum exhaust operation for the process chamber 18 or stop the vacuum exhaust operation. In addition, with the vacuum pump 36 in operation, the inner pressure of the process chamber 18 may be adjusted by adjusting an opening degree of the APC valve 34 based on pressure information detected by the pressure sensor 32. An exhauster (which is an exhaust structure or an exhaust system) is constituted mainly by the exhaust pipe 120, the APC valve 34 and the pressure sensor 32. The exhauster may further include the vacuum pump 36.

A seal cap 38 serving as a furnace opening lid capable of airtightly sealing (closing) a lower end opening of the reaction tube 16 is provided under the reaction tube 16. For example, the seal cap 38 is made of a metal material such as SUS and stainless steel, and is of a disk shape. An O-ring 40 serving as a seal is provided on an upper surface of the seal cap 38 so as to be in contact with the lower end of the reaction tube 16. When the manifold is provided under the reaction tube 16, O-rings 40 are provided between the reaction tube 16 and the manifold and between the manifold and the seal cap 38. In such a case, the process chamber 18 is defined by the reaction tube 16, the manifold and the seal cap 38.

The seal cap 38 is configured to be in contact with the lower end of the reaction tube 16 from thereunder in the vertical direction, and is configured to be elevated or lowered in the vertical direction by a boat elevator 46 serving as an elevating structure vertically installed outside the reaction tube 16. That is, the boat elevator 46 is configured to be capable of transferring (loading) the boat 20 into and transferring (unloading) the boat 20 out of the process chamber 18 by elevating and lowering the seal cap 38. In other words, the boat elevator 46 is configured as a transfer apparatus (which is a transfer structure) capable of loading the boat 20 (that is, the wafers 2 accommodated in the boat 20) into the process chamber 18 and capable of unloading the boat 20 (that is, the wafers 2 accommodated in the boat 20) out of the process chamber 18.

The boat 20 serving as a substrate support is configured such that the plurality of wafers 2 (for example, 25 wafers to 200 wafers) are supported (or stacked) in the vertical direction in the boat 20 while the wafers 2 are horizontally oriented with their centers aligned with one another in a multistage manner. For example, the boat 20 is made of a heat resistant material such as quartz and SiC. A plurality of heat insulation plates 48 are vertically arranged in a multistage manner below a lowermost wafer (or lowermost wafers) among the wafers 2 accommodated in the boat 20. Each of the heat insulation plates 48 is of a disk shape, and an outer diameter of each of the heat insulation plates 48 is substantially the same as an outer diameter of the wafer 2. For example, each of the heat insulation plates 48 is made of a material with a low thermal capacity and a high emissivity, such as quartz, silicon (Si) and SiC. With such a configuration, it is possible to easily absorb a radiant heat from a subsidiary heater 50 described in detail later. Thereby, it is possible to improve a temperature responsiveness of the wafers 2 during a temperature recovery, and it is also possible to shorten a recovery time. In addition, in the present specification, a notation of a numerical range such as “from 25 wafers to 200 wafers” means that a lower limit and an upper limit are included in the numerical range. Therefore, for example, a numerical range “from 25 wafers to 200 wafers” means a range equal to or higher than 25 wafers and equal to or less than 200 wafers. The same also applies to other numerical ranges described in the present specification.

A rotator (which is a rotating structure) 42 configured to rotate the boat 20 is installed at the seal cap 38 opposite to the process chamber 18. The rotator 42 includes a housing 56 which is of a substantially cylindrical shape with an open upper end and a closed lower end. The housing 56 is arranged at and fixed to a lower surface of the seal cap 38 to be aligned in a manner concentric with the seal cap 38. An inner shaft 58 (which is of an elongated thin cylindrical shape) is disposed in the vertical direction within the housing 56, and is fixedly supported by a closing wall of the housing 56. An outer shaft 60 (which is of a cylindrical shape whose diameter is greater than an outer diameter of the inner shaft 58) is disposed in the housing 56 to be aligned in a manner concentric with the housing 56. An upper end of the outer shaft 60 is of a hollow disk shape. That is, at a central portion of the upper end of the outer shaft 60, a through-hole (through which the subsidiary heater 50 is inserted) is provided. The outer shaft 60 is rotatably supported by: a pair of upper and lower inner bearings 62 and 64 disposed between the inner shaft 58 and the outer shaft 60; and a pair of upper and lower outer bearings 66 and 68 disposed between the outer shaft 60 and the housing 56. The subsidiary heater 50 described in detail later is inserted vertically into the inner shaft 58.

A rotating shaft 54 of a substantially cylindrical shape is fixed to an upper surface of the outer shaft 60. A lower end of the rotating shaft 54 is of an outward flange shape, and a through-hole (through which the subsidiary heater 50 penetrates) is provided at a central portion of the rotating shaft 54. A base support 96 of a substantially cylindrical shape is fixed to an upper end of the rotating shaft 54 and the upper surface of the seal cap 38. The base support 96 is of an outward flange shape, and a through-hole (through which the subsidiary heater 50 penetrates) is provided at a central portion of the base support 96. For example, the base support 96 is made of a heat resistant material such as quartz and SiC.

A heat insulator holder 110 is fixed to the upper surface of the seal cap 38. For example, the heat insulator holder 110 is constituted by: an upper plate 112 of a disk shape; a lower plate 114 of a hollow disk shape whose outer diameter is substantially the same as that of the upper plate 112 and whose inner diameter is greater than that of the base support 96; and three support columns 116 connecting the upper plate 112 and the lower plate 114. The subsidiary heater (also referred to as cap heater) 50 serving as a second heater (which is an auxiliary heating apparatus, an auxiliary heating structure or an auxiliary heater) is disposed below the upper plate 112. A plurality of heat insulators 108 made of quartz are arranged below the subsidiary heater 50 at support recesses engraved at each of the three support columns 116 at equal intervals.

The boat 20 is connected to an upper portion of the heat insulator holder 110 via a support column 99. That is, the upper plate 112 and a boat plate 98 of a disk shape attached to a lower end of the boat 20 are connected by the support column 99 provided concentrically with the upper plate 112 and the boat plate 98.

For example, the heater 14 is divided into five control zones (that is, “U”, “CU”, “C, “CL” and “L” shown in FIG. 1), from an upper end to a lower end thereof. The heater 14 is configured to heat each zone in the process vessel to a target temperature. In addition, the subsidiary heater 50 is configured to assist in heating a specific zone, for example, the lowest zone L among the zones mentioned above. In other words, the zone L is a zone (among the zones mentioned above) in which a temperature detected by a temperature sensor 52 fluctuates the most (that is, a temperature fluctuation is the largest), and is, for example, a zone in which the temperature is most likely to be lowered. With such a configuration, it is possible to heat the wafer 2 (that is, the lowermost wafer) among the wafers 2 accommodated in the boat 20, and it is also possible to elevate the temperature (that is, it is possible to perform a temperature elevating step) of each of the wafers 2 to a predetermined temperature at a predetermined time. Hereinafter, the lowermost wafer (or the lowermost wafers) may also be referred to as a “lowermost wafer 2” (or “lowermost wafers 2”). By using the subsidiary heater 50 in addition to the heater 14 to heat the wafers 2 as described above, even when the wafer 2 is located in a zone (for example, the zone L) in which a temperature of the wafer 2 is less likely to be elevated, it is possible to elevate the temperature of the wafer 2 to the target temperature without delay. Thereby, it is possible to shorten a temperature elevation time (the temperature elevating step) without lengthening it.

Alternatively, when the lowermost wafer 2 (or the lowermost wafers 2) (among the wafers 2 accommodated in the boat 20) is (or are) located in the zone CU, the subsidiary heater 50 described later is configured to be located in the vicinity of the lowermost wafer 2 (or the lowermost wafers 2) accommodated in the boat 20. In other words, the subsidiary heater 50 described later is preferably located in the zone where the lowermost wafer 2 (or the lowermost wafers 2) is (or are) located, near a lower side of the lowermost wafer 2. By heating the wafers 2 using the subsidiary heater 50 in addition to the heater 14, it is possible to heat the lowermost wafer 2 (or the lowermost wafers 2) among the wafers 2 accommodated in the boat 20, and it is also possible to elevate the temperature (that is, it is possible to perform the temperature elevating step) of each of the wafers 2 to the predetermined temperature at the predetermined time. In the present embodiments, the lowermost wafers 2 may refer to several to about a dozen wafers (among the wafers 2 accommodated in the boat 20) from a lower end of the wafers 2 (that is, from the first wafer from the bottom).

Thermocouples 302 are provided on an inner wall of the heater 14 at positions corresponding to each zone. The thermocouples 302 are configured as heater thermocouples, and are configured to detect a temperature of heater 14 in each zone. Hereinafter, the temperature detected by the thermocouples 302 may also be referred to as a “heater TC detection temperature”. Hereinafter, the heater TC detection temperature may also be referred to as a “heater temperature.”

The temperature sensor 52 serving as a first temperature sensor is provided in the annular space between the inner wall of the reaction tube 16 and the wafers 2. Similar to the nozzle 22, the temperature sensor 52 is L-shaped, and is provided along the inner wall of the reaction tube 16. Thermocouples 303 are provided at the temperature sensor 52 at positions corresponding to each zone. The thermocouples 303 are configured as cascade thermocouples, and are configured to detect a temperature (inner temperature) of the process chamber 18 (which is formed in the reaction tube 16) in each zone. Hereinafter, the temperature detected by thermocouples 303 may also be referred to as a “furnace TC detection temperature” or a “furnace temperature” which is an inner temperature of a furnace.

Specifically, a controller 200 serving as a control structure described in detail later is configured to control the inner temperature of the process chamber 18 (that is, the inner temperature of the furnace) to a target temperature by adjusting a state of electric conduction to each zone of the heater 14 and a state of electric conduction to the subsidiary heater 50 based on temperature information detected by the thermocouples 302 and the thermocouples 303 in each zone and thermocouples 304 described later.

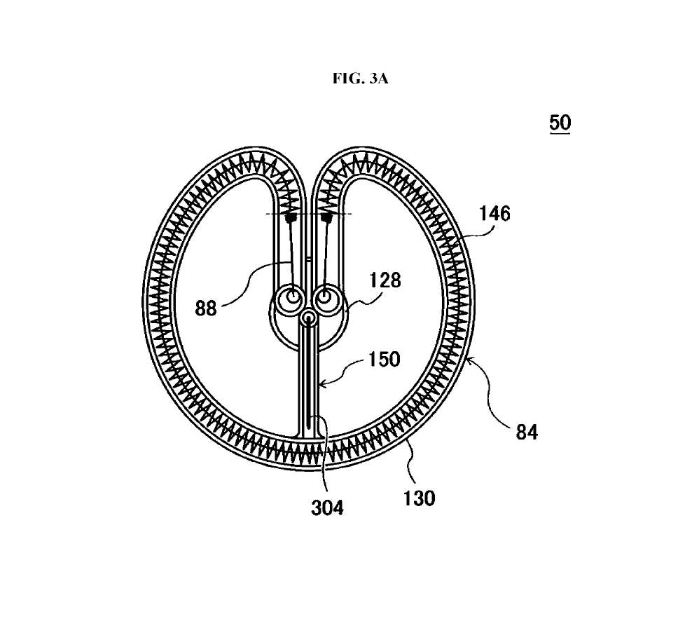

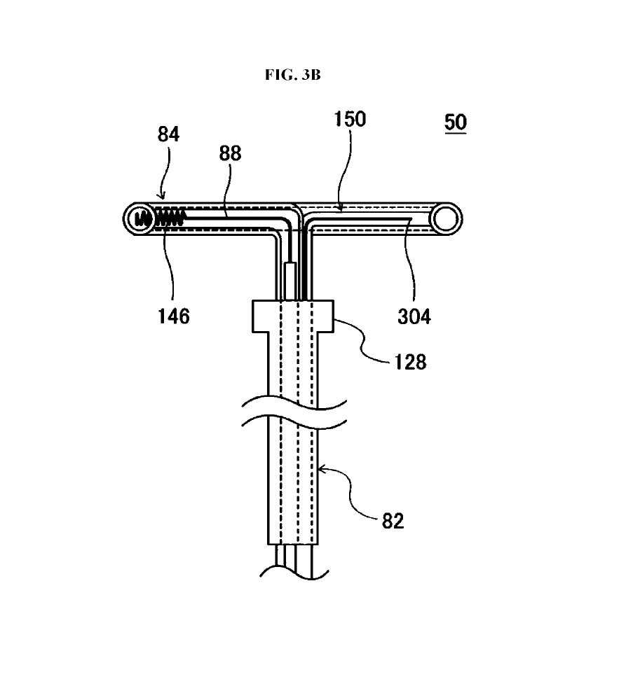

Subsequently, the subsidiary heater 50 according to the present embodiments will be described in detail with reference to FIGS. 3A and 3B.

The subsidiary heater 50 includes a support column 82 extending vertically and a heating element (which is a heat generating structure) 84 installed approximately (substantially) horizontally relative to the support column 82.

The heating element 84 is of a substantially annular shape whose diameter is smaller than the outer diameter of the wafer 2, and is configured to be supported horizontally relative to the support column 82 at an upper end of the support column 82. In other words, the heating element 84 is supported so as to be parallel to the wafer 2. Inside the heating element 84, a heater wire 88 serving as a resistive heating wire (which constitutes a resistance heating element 146 of a coil shape) is contained. For example, the resistance heating element 146 is made of a material such as Fe-Cr-Al alloy and molybdenum disilicide. Both ends of the heater wire 88 are bent downward in the vertical direction at a connection portion between the support column 82 and the heating element 84, and are drawn into an inside (inner portion) of the support column 82.

A protrusion (which is an expanded structure) 128 whose cross-sectional area is greater than a cross-sectional area of a portion provided below the protrusion 128 (that is, a cross-sectional area of the support column 82) is provided at the upper end of the support column 82. The heating element 84 is connected to an upper surface of the protrusion 128. The heating element 84 is configured as a ring shape whose start point and end point are provided at the upper surface of the protrusion 128.

A temperature sensor 150 serving as a second temperature sensor configured to detect a temperature of the subsidiary heater 50 is provided in the subsidiary heater 50 so as to penetrate the support column 82. The temperature sensor 150 is curved in a horizontal direction at an upper portion thereof such that a cross-section thereof is substantially L-shaped. The temperature sensor 150 is configured as a tubular structure, and the thermocouples 304 are attached to a front end (tip) of the temperature sensor 150. The temperature sensor 150 is bent in the horizontal direction above the protrusion 128 (that is, at a center of an annular structure 130), and extends such that the temperature sensor 150 is connected to an outer wall of the annular structure 130. A horizontal portion of the temperature sensor 150 is provided parallel to the heating element 84. In addition, a height position of the temperature sensor 150 in the horizontal direction is set so as to coincide with a height of a center position of a diameter of the annular structure 130 when viewed from a vertical cross-section of the subsidiary heater 50. According to the present embodiments, the term “height position of the temperature sensor 150 in the horizontal direction” may refer to a height of a center position of a diameter of the horizontal portion when the temperature sensor 150 is viewed from the vertical cross-section. The thermocouples 304 of the temperature sensor 150 are installed so as to be located in the vicinity of the outer wall of the annular structure 130, and are configured to detect the temperature of the subsidiary heater 50.

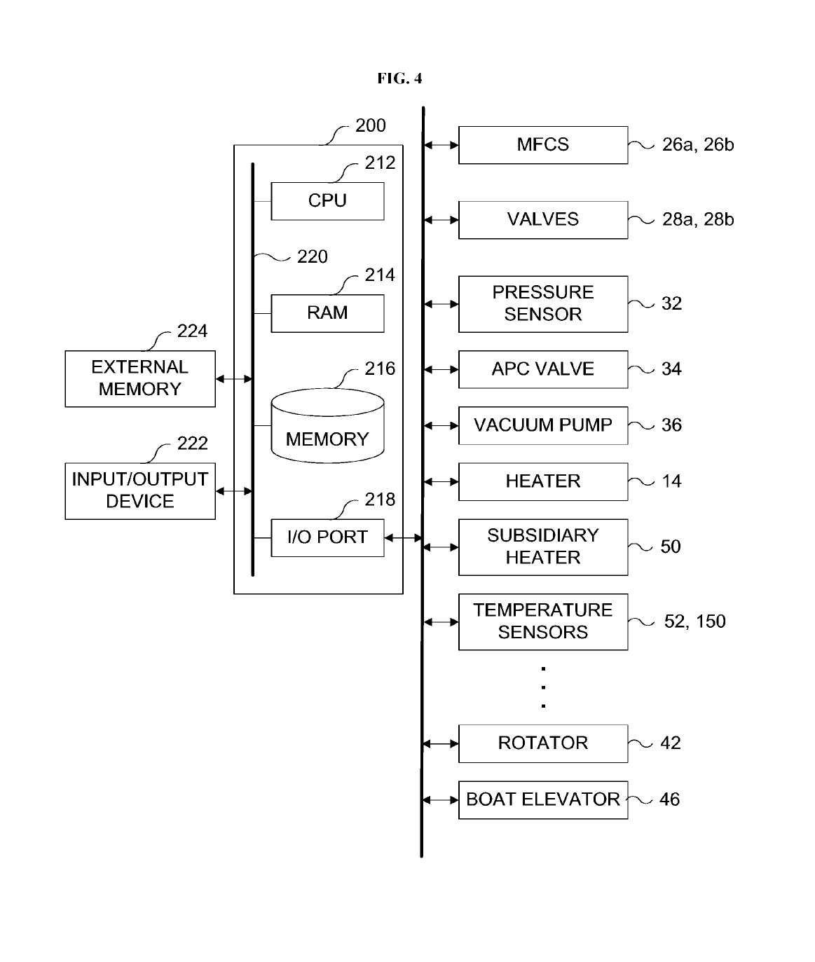

As shown in FIG. 4, the controller 200 serving as the control structure (control apparatus) is constituted by a computer including a CPU (Central Processing Unit) 212, a RAM (Random Access Memory) 214, a memory 216 and an I/O port (input/output port) 218. The RAM 214, the memory 216 and the I/O port 218 are configured to be capable of exchanging data with the CPU 212 through an internal bus 220. For example, an input/output device 222 constituted by a component such as a touch panel is connected to the controller 200.

For example, the memory 216 is configured by a component such as a flash memory and a hard disk drive (HDD). For example, a control program configured to control an operation of the substrate processing apparatus 10 and a process recipe containing information on procedures and conditions of a substrate processing described later may be readably stored in the memory 216. The process recipe is obtained by combining steps (procedures) of the substrate processing described later such that the controller 200 can execute the steps to acquire a predetermined result, and functions as a program. Hereinafter, the process recipe and the control program may be collectively or individually referred to as a “program” or a “program product.” Thus, in the present specification, the term “program” may refer to the process recipe alone, may refer to the control program alone or may refer to both of the process recipe and the control program. The RAM 214 functions as a memory area (work area) where a program or data read by the CPU 212 is temporarily stored.

The I/O port 218 is connected to the components described above such as the MFCs 26a and 26b, the valves 28a and 28b, the pressure sensor 32, the APC valve 34, the vacuum pump 36, the heater 14, the subsidiary heater 50, the temperature sensors 52 and 150, the rotator 42 and the boat elevator 46.

The CPU 212 is configured to read the control program from the memory 216 and execute the control program read from the memory 216. In addition, the CPU 212 is configured to read the process recipe from the memory 216, for example, in accordance with an operation command inputted from the input/output device 222. In accordance with contents of the process recipe read from the memory 216, the CPU 212 may be configured to control various operations such as flow rate adjusting operations for various gases by the MFCs 26a and 26b, opening and closing operations of the valves 28a and 28b, an opening and closing operation of the APC valve 34, a pressure regulating operation (pressure adjusting operation) by the APC valve 34 based on the pressure sensor 32, a start and stop operation of the vacuum pump 36, a temperature regulating operation (temperature adjusting operation) by the heater 14 and the subsidiary heater 50 based on the temperature sensors 52 and 150, an operation of adjusting a rotation and a rotation speed of the boat 20 by the rotator 42 and an elevating and lowering operation of the boat 20 by the boat elevator 46.

The controller 200 may be embodied by installing the above-described program stored in an external memory 224 into the computer. For example, the external memory 224 may include a magnetic tape, a magnetic disk such as a flexible disk and a hard disk, an optical disk such as a CD and a DVD and a semiconductor memory such as a USB memory or a memory card. The memory 216 or the external memory 224 may be embodied by a non-transitory computer readable recording medium storing a program. Hereafter, the memory 216 and the external memory 224 may be collectively or individually referred to as a “recording medium”. Thus, in the present specification, the term “recording medium” may refer to the memory 216 alone, may refer to the external memory 224 alone, or may refer to both of the memory 216 and the external memory 224. For example, instead of the external memory 224, a communication interface such as the Internet and a dedicated line may be used for providing the program to the computer.

### Substrate Processing

Hereinafter, an example of a substrate processing sequence of forming a film on the wafer 2 (hereinafter, also referred to as a “film forming process”) and annealing the film formed on the wafer 2 (hereinafter, also referred to as an “annealing process”), which is performed as a part of a manufacturing process of a semiconductor device, will be described. The substrate processing sequence is performed by using the substrate processing apparatus 10 described above. In the following description, operations of components constituting the substrate processing apparatus 10 are controlled by the controller 200.

In the present specification, the term “wafer” may refer to “a wafer itself,” or may refer to “a wafer and a stacked structure (aggregated structure) of a predetermined layer (or layers) or a film (or films) formed on a surface of the wafer.” In the present specification, the term “a surface of a wafer” may refer to “a surface of a wafer itself,” or may refer to “a surface of a predetermined layer (or a predetermined film) formed on a wafer.” Thus, in the present specification, “forming a predetermined layer (or a film) on a wafer” may refer to “forming a predetermined layer (or a film) directly on a surface of a wafer itself,” or may refer to “forming a predetermined layer (or a film) on a surface of another layer (or another film) formed on a wafer.” In the present specification, the terms “substrate” and “wafer” may be used as substantially the same meaning.

### Wafer Charging Step and Boat Loading Step

The wafers 2 are charged (transferred) into the boat 20 (wafer charging step). Then, the boat 20 is elevated by the boat elevator 46 and thereby loaded (transferred) into the process chamber 18 (boat loading step). In such a state, the seal cap 38 airtightly seals the lower end of the reaction tube 16 via the O-ring 40.

### Pressure Adjusting Step and Temperature Adjusting Step

Then, the vacuum pump 36 vacuum-exhausts (decompresses and exhausts) the inner atmosphere of the process chamber 18 (that is, a space in which the wafers 2 are present (accommodated)) such that the inner pressure of the process chamber 18 reaches and is maintained at a predetermined pressure (vacuum level). In such an operation, the inner pressure of the process chamber 18 is measured by the pressure sensor 32, and the APC valve 34 is feedback-controlled based on the pressure information detected by the pressure sensor 32 (pressure adjusting step). The vacuum pump 36 continuously vacuum-exhausts the inner atmosphere of the process chamber 18 until at least a processing of the wafer 2 is completed.

In addition, the heater 14 and the subsidiary heater 50 heats the process chamber 18 such that the inner temperature of the process chamber 18 reaches and is maintained at a predetermined temperature. In such an operation, the state of the electric conduction to the heater 14 is feedback-controlled based on the temperature information detected by the temperature sensor 52 such that a predetermined temperature distribution of the inner temperature of the process chamber 18 can be obtained. In addition, with respect to a specific zone alone, the state of the electric conduction to the heater 14 is feedback-controlled based on the temperature information detected by each of the temperature sensors 52 and 150 (temperature adjusting step). Further, the state of electric conduction to the subsidiary heater 50 may be feedback-controlled based on the temperature information detected by the temperature sensor 150. The heater 14 and the subsidiary heater 50 continuously heat the process chamber 18 until at least the processing of the wafer 2 is completed. Alternatively, in the present step, the heating for the process chamber 18 by the subsidiary heater 50 may be stopped. In other words, because the subsidiary heater 50 is controlled separately from the heater 14, the heating by the subsidiary heater 50 may be disabled, and the wafers 2 in the process chamber 18 may be heated by the heater 14 alone.

In addition, the rotation of the boat 20 (and the wafers 2 accommodated in the boat 20) is started by the rotator 42. As the boat 20 is rotated by the rotator 42, the wafers 2 are also rotated. In such an operation, the heat insulators 108 and the subsidiary heater 50 are not rotated. The rotator 42 continuously rotates the boat 20 and the wafers 2 until at least the processing of the wafer 2 is completed. According to the present embodiments, the heat insulator holder 110 including the heat insulators 108 is fixed. However, the heat insulator holder 110 including the heat insulators 108 may be configured to be rotated by the rotator 42 in the same manner as the boat 20.

### Film Forming Process

When the inner temperature of the process chamber 18 is stabilized at a process temperature (which is set in advance), a source gas is supplied to the wafers 2 in the process chamber 18. In the present specification, the term “process temperature” refers to the furnace temperature (that is, the inner temperature of the furnace) or a temperature (inner temperature) of the process vessel (that is, the inner temperature of the process chamber 18).

Specifically, the valve 28a is opened to supply the source gas into the gas supply pipe 24a. The source gas whose flow rate is adjusted by the MFC 26a is supplied into the process chamber 18 through the nozzle 22, and is exhausted through the exhaust pipe 120. Thereby, the source gas is supplied to the wafers 2. In such an operation, simultaneously with a supply of the source gas, the valve 28b may be opened to supply the inert gas into the gas supply pipe 24b. In such a case, the inert gas whose flow rate is adjusted by the MFC 26b is supplied into the process chamber 18 together with the source gas through the nozzle 22, and is exhausted through the exhaust pipe 120.

After a predetermined film containing a source element of the source gas is formed on the wafer 2, the valve 28a is closed to stop the supply of the source gas. In such an operation, with the APC valve 34 open, the process chamber 18 is vacuum-exhausted by the vacuum pump 36 to discharge the source gas (which remains unreacted or which contributed to a film formation) remaining in the process chamber 18 from the process chamber 18. In such an operation, the valve 28b may be opened to supply the inert gas to the process chamber 18. Thereby, it is possible to improve an effect of exhausting the gas (which remains in the process chamber 18) from the process chamber 18.

As described above, according to the present embodiments, for example, the film is formed by simply supplying the source gas. However, the film forming process is not limited thereto. For example, the source gas and a reactive gas (not shown) may be supplied simultaneously, or the source gas and the reactive gas (not shown) may be supplied in a cyclical manner. For example, a container (not shown) may be provided to temporarily store the gas. Then, a predetermined amount of the source gas may be stored in the container and then released all at once to supply the source gas to the process chamber 18.

For example, while performing the film forming process mentioned above, the controller 200 may control the state of electric conduction to the subsidiary heater 50 described later.

### Temperature Elevating Step

After the film forming process is completed, that is, after the predetermined film is formed on the wafer 2, the wafer 2 in the process chamber 18 is heated by the heater 14 and the subsidiary heater 50 to a target temperature, that is, an annealing temperature higher than the process temperature in the film forming process described above. In such an operation, the valve 28b is opened to supply the inert gas into the process chamber 18 through the nozzle 22. Then, the inert gas is exhausted through the exhaust pipe 120 to purge the process chamber 18.

### Annealing Process

After the inner temperature of the process chamber 18 reaches the target temperature and is stabilized, a heat treatment process (annealing process) is performed on the wafer 2 in the process chamber 18, that is, the predetermined film formed on the wafer 2.

### Purge Step and Returning to Atmospheric Pressure Step

After the annealing process is completed, the valve 28b is opened to supply the inert gas into the process chamber 18 through the gas supply pipe 24b. Then, the inert gas is exhausted through the exhaust pipe 120. The inert gas acts as a purge gas. Thereby, the process chamber 18 is purged with the inert gas. As a result, the gas remaining in the process chamber 18 and reaction by-products remaining in the process chamber 18 are removed from the process chamber 18 (purge step). Thereafter, the inner atmosphere of the process chamber 18 is replaced with the inert gas (substitution by the inert gas), and the inner pressure of the process chamber 18 is returned to the normal pressure (returning to an atmospheric pressure step).

Boat Unloading Step and Wafer Discharging Step

The seal cap 38 is lowered by the boat elevator 46, and the lower end of the reaction tube 16 is opened. The boat 20 with the wafers 2 (which are processed) supported therein is unloaded out of the reaction tube 16 through the lower end of the reaction tube 16 (boat unloading step). Then, the wafers 2 (which are processed) are discharged out of the boat 20 (wafer discharging step).

As in the substrate processing described above, the annealing process may be performed in the same process furnace, that is, the process furnace 12 (or the process chamber 18) following the film forming process. In such a case, for example, when the temperature during the film forming process is within a range from 500 °C to 700 °C, the target temperature for the annealing process may be 800 °C or higher. In such a substrate processing, the target temperature for the annealing process is inevitably set to be higher than a specification temperature of the subsidiary heater 50. In addition, since the subsidiary heater 50 uses a wire whose diameter is smaller than that of the heater 14, the temperature (the specification temperature) at which the subsidiary heater 50 can be controlled is lower than that of the heater 14. Therefore, when the subsidiary heater 50 is used at a temperature higher than the specification temperature (at which the subsidiary heater 50 can be controlled), a wire temperature of the subsidiary heater 50 is elevated (increased) significantly. Thereby, a deterioration of the wire of the subsidiary heater 50 may be accelerated. As a result, the life of the subsidiary heater 50 may be shortened. In addition, since the subsidiary heater 50 is installed at a lower portion of the process furnace 12 (or the process chamber 18), when modifying the diameter of the wire to increase (be thickened), a design change to components around the furnace opening may be required. In addition, when the wire temperature is suppressed by limiting the maximum output of the heater 14 simply to extend (or lengthen) the life of the subsidiary heater 50, the temperature elevation time may be lengthened, and the throughput may be reduced.

According to the embodiments of the present disclosure, the controller 200 is configured to be capable of performing a temperature control at a temperature range higher than the specification temperature of the subsidiary heater 50 by selecting at least one among temperature control methods shown in first to third modes described below or by combining the temperature control methods shown in the first to third modes described below. Needless to say, the controller 200 is configured to be capable of controlling the heater 14 (which is divided into the zones and configured to heat the process vessel in which the wafer 2 is arranged) and the subsidiary heater 50 (which is configured to assist in heating the specific zone). As a result, by suppressing an increase in the wire temperature of the subsidiary heater 50, it is possible to suppress the deterioration of the wire of the subsidiary heater 50.

For example, the controller 200 is configured to be capable of heating each zone to a target temperature in each step by appropriately combining: (i) heating by both of the heater 14 and the subsidiary heater 50 and (ii) heating by the heater 14 alone.

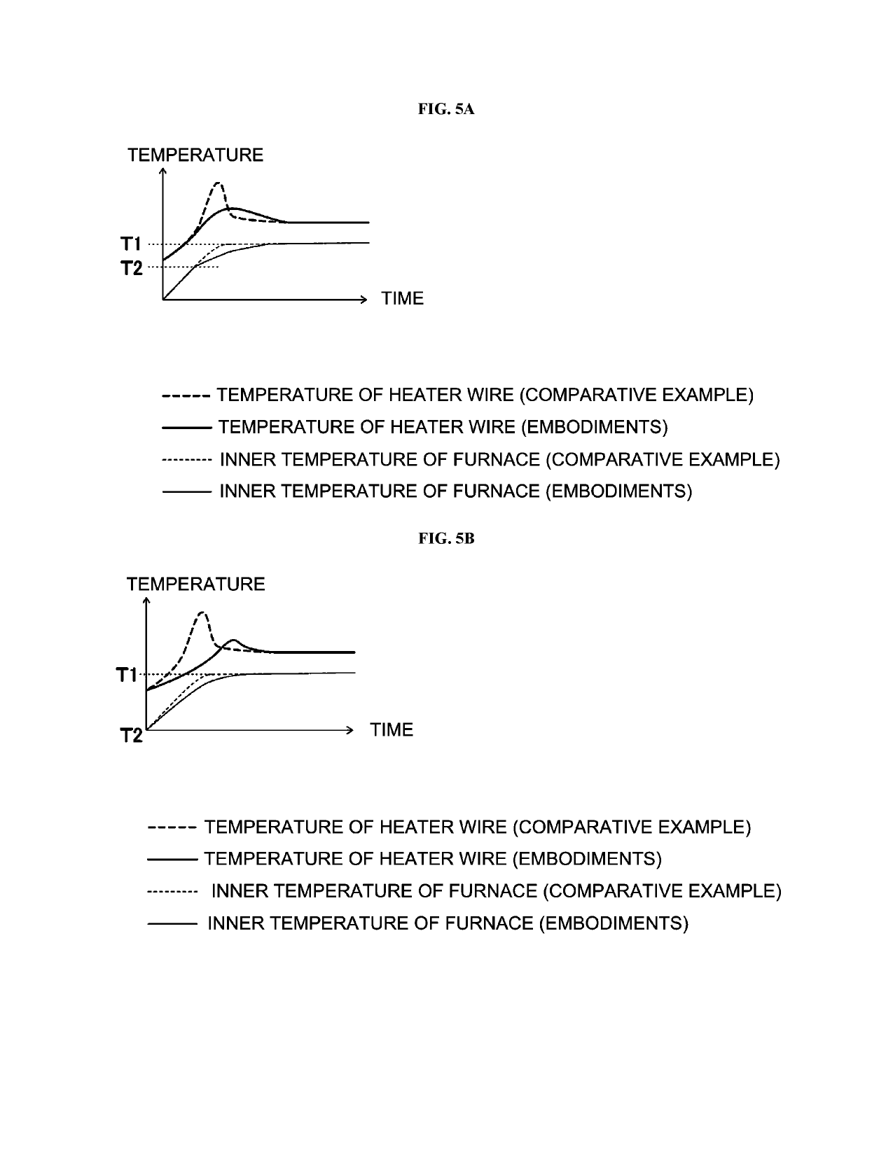

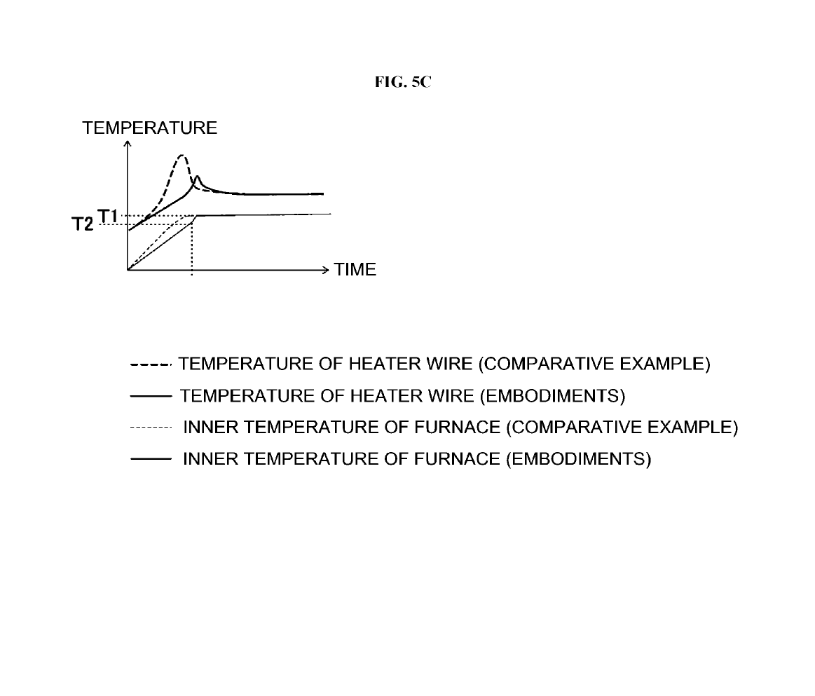

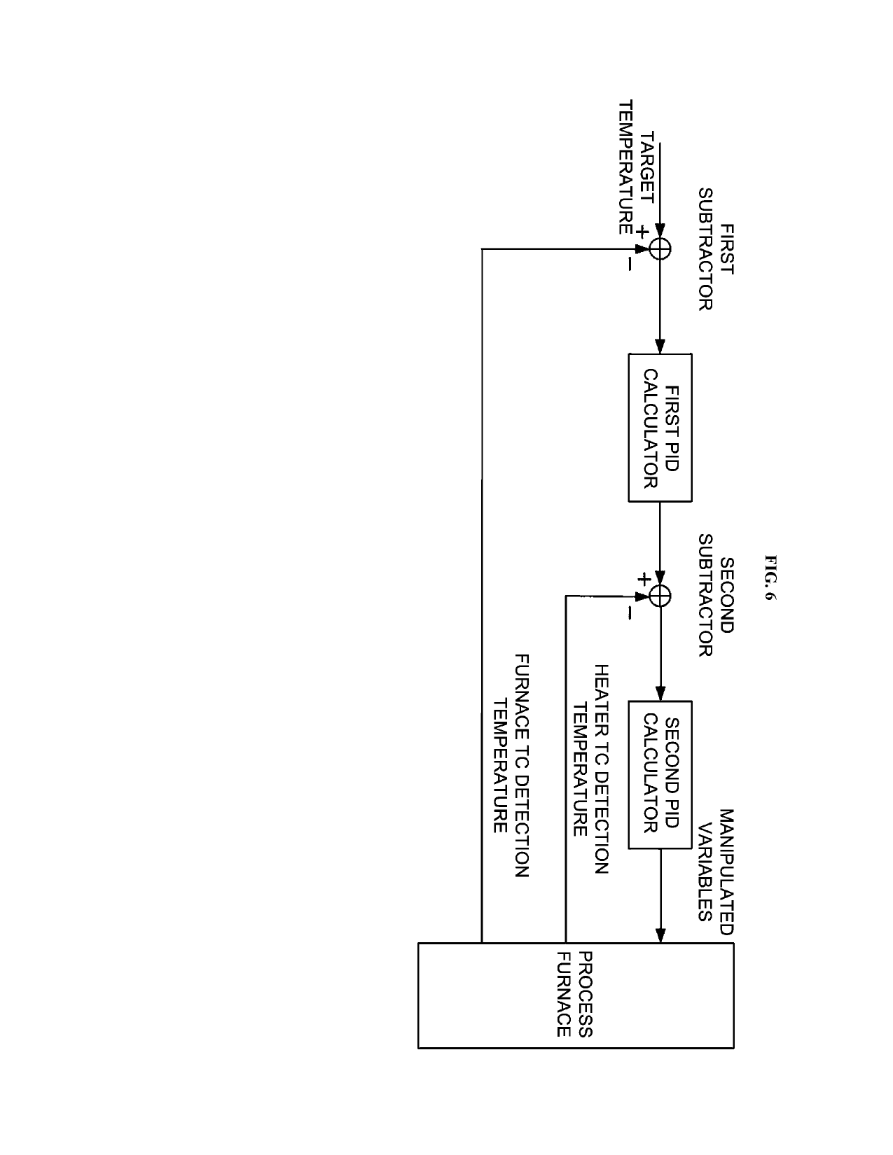

FIG. 5A is a diagram schematically illustrating a case where an output of the subsidiary heater 50 is limited when the wire temperature of the subsidiary heater 50 is equal to or higher than a predetermined temperature. FIG. 5B is a diagram schematically illustrating a case where a temperature elevation rate of the subsidiary heater 50 is reduced when the wire temperature of the subsidiary heater 50 is equal to or higher than the predetermined temperature. FIG. 5C is a diagram schematically illustrating a case where a start of the output of the subsidiary heater 50 is delayed until the wire temperature of the subsidiary heater 50 is equal to or higher than the predetermined temperature. In FIGS. 5A to 5C, a thin dashed line indicates the furnace temperature (that is, the inner temperature of the furnace) in a comparative example, and a thick dashed line indicates the wire temperature of the subsidiary heater 50 in the comparative example. According to the comparative example, in the temperature elevating step of the substrate processing described above, in addition to the heater 14, the wafer 2 is heated by the subsidiary heater 50 while the output of the subsidiary heater 50 is set to 100 % of maximum. In each of FIGS. 5A to 5C, a thin solid line indicates the furnace temperature in each of the first to third modes, and a thick solid line indicates the wire temperature of the subsidiary heater 50 in each of the first to third modes.

As shown in FIGS. 5A to 5C, in addition to the heater 14, when the output of the subsidiary heater 50 is set to 100 %, the wire temperature of the subsidiary heater 50 may temporarily exceed the specification temperature (at which the subsidiary heater 50 can be controlled) before the furnace temperature reaches and is stabilized at a target temperature T1. For example, when elevating (increasing) a temperature of the zone L to the target temperature T1, the controller 200 controls the subsidiary heater 50 to perform at least one among the first to third modes described below. For example, at least two among the first to third modes described below may be used in combination.

### First Mode

According to the first mode, the controller 200 freely controls the output of the subsidiary heater 50 by keeping the output constant or fluctuating (or varying) the output without any particular restrictions, until the wire temperature detected by the temperature sensor 150 reaches a predetermined temperature T2 (which is lower than the target temperature T1). Then, when the wire temperature of the subsidiary heater 50 reaches or exceeds the predetermined temperature T2, the controller 200 limits the output of the subsidiary heater 50. That is, the controller 200 controls the heater 14 and the subsidiary heater 50 such that the inner temperature of the process vessel (that is, the furnace temperature detected in each zone by the temperature sensor 52) reaches the target temperature T1, and when the temperature of the subsidiary heater 50 detected by the temperature sensor 150 reaches the predetermined temperature T2, the controller 200 limits the output of the subsidiary heater 50. Specifically, for example, when the temperature is equal to or higher than the predetermined temperature T2 (which is lower than the target temperature T1), the controller 200 controls the output of the subsidiary heater 50 to be limited to, for example, 0 (zero) % to 30 % of the maximum output (100 %). In addition, the controller 200 is capable of controlling the wire temperature of the subsidiary heater 50 based on a predetermined relationship between the heater temperature in the zone L, the output (output value) of the subsidiary heater 50 and the wire temperature of the subsidiary heater 50. As a result, as shown in FIG. 5A, a peak value of the wire temperature of the subsidiary heater 50 can be set to be lower than a peak value of the wire temperature of the subsidiary heater 50 in the comparative example. In addition, by suppressing the increase in the wire temperature of the subsidiary heater 50, it is possible to suppress the deterioration of the wire of the subsidiary heater 50.

According to the present embodiments, an output limit value for limiting the output of the subsidiary heater 50 when the temperature of the subsidiary heater 50 (that is, the temperature detected by the temperature sensor 150) is equal to or higher than the predetermined temperature T2 (which is lower than the target temperature T1) can be stored and maintained in a component such as the memory 216 in advance.

For example, when the temperature detected by the temperature sensor 150 reaches the predetermined temperature T2, in a case where the output of the subsidiary heater 50 exceeds the output limit value (which is set in advance), the controller 200 is configured to be capable of controlling the output of the subsidiary heater 50 to be lower than or equal to the output limit value. Thereby, it is possible to suppress the increase in the wire temperature of the subsidiary heater 50, and it is also possible to reduce the deterioration (wear and tear) of the wire of the subsidiary heater 50.

For example, until the temperature detected by the temperature sensor 150 reaches the predetermined temperature T2 and the temperature of each zone detected by the temperature sensor 52 reaches the target temperature T1, the controller 200 may fluctuate (or vary) the output of the subsidiary heater 50 from 0 or more to an output equal to or less than the output limit value (which is set in advance), or may keep the output constant at a pre-set output equal to or less than the output limit value. Thereby, it is possible to suppress the increase in the wire temperature of the subsidiary heater 50, and it is also possible to reduce the deterioration (wear and tear) of the wire of the subsidiary heater 50.

For example, until the temperature detected by the temperature sensor 150 reaches the predetermined temperature T2 and the temperature of each zone detected by the temperature sensor 52 reaches the target temperature T1, the controller 200 may set the output of the subsidiary heater 50 to 0, or may fluctuate (or vary) the output of the subsidiary heater 50 in a pulsed manner between a zero (0) output and the pre-set output (which is greater than 0 and equal to or less than the output limit value). Even with such a configuration, it is possible to suppress the increase in the wire temperature of the subsidiary heater 50, and it is also possible to reduce the deterioration (wear and tear) of the wire of the subsidiary heater 50.

For example, in a case where the output of the subsidiary heater 50 is equal to or less than the output limit value (which is set in advance) when the temperature detected by the temperature sensor 150 reaches the predetermined temperature T2, the controller 200 may control the output of the subsidiary heater 50 to fluctuate (or vary) at or below the output when the predetermined temperature T2 is reached until the temperature of each zone detected by the temperature sensor 52 reaches the target temperature T1. Even with such a configuration, it is possible to suppress the increase in the wire temperature of the subsidiary heater 50, and it is also possible to reduce the deterioration (wear and tear) of the wire of the subsidiary heater 50.

In a manner described above, when the temperature detected by the temperature sensor 150 is equal to or higher than the predetermined temperature T2, as long as the output of the subsidiary heater 50 is equal to or lower than the output limit value (which is set in advance), the controller 200 can heat the process vessel and each zone using both of the heater 14 and the subsidiary heater 50. Therefore, according to the first mode, it is possible to suppress the increase in the wire temperature of the subsidiary heater 50, and it is also possible to reduce the deterioration (wear and tear) of the wire of the subsidiary heater 50. As a result, it is possible to extend (or lengthen) the life of the subsidiary heater 50. In addition, by limiting the output of the subsidiary heater 50, it is possible to reduce a power load on the entire heaters.

### Second Mode

According to the second mode, the controller 200 sets the temperature elevation rate of the subsidiary heater 50 to be lower than a temperature elevation rate of the heater 14 based on the wire temperature and the furnace temperature. The controller 200 keeps the output of the subsidiary heater 50 constant until the wire temperature of the subsidiary heater 50 detected by the temperature sensor 150 reaches the predetermined temperature T2 (which is lower than the target temperature T1). Then, when the wire temperature of the subsidiary heater 50 reaches or exceeds the predetermined temperature T2, the controller 200 sets the temperature elevation rate of the subsidiary heater 50 to be lower than the temperature elevation rate of the heater 14. As a result, as shown in FIG. 5B, a peak value of the wire temperature of the subsidiary heater 50 can be set to be lower than a peak value of the wire temperature of the subsidiary heater 50 in the comparative example. In addition, by suppressing the increase in the wire temperature of the subsidiary heater 50, it is possible to suppress the deterioration of the wire of the subsidiary heater 50.

For example, in the second mode, the temperature elevation rate of the subsidiary heater 50 may be set to be lower than the temperature elevation rate of the heater 14 from a start of elevating the temperature to the target temperature T1. In addition, as long as the increase in the wire temperature of the subsidiary heater 50 is suppressed, the output limit value (which is higher than or equal to the predetermined temperature T2) in the first mode may not be used.

### Third Mode

According to the third mode, the controller 200 delays the start of the output of the subsidiary heater 50 relative to a start of the output of the heater 14, depending on the wire temperature and the furnace temperature. As an example, the controller 200 is configured to start the output of the subsidiary heater 50 when the temperature of the zone L detected by the temperature sensor 52 reaches the predetermined temperature T2. For example, the controller 200 is configured to adjust the output of the subsidiary heater 50 to an output equal to or less than the output limit value (which is set in advance). In such a manner, it is possible set a time for turning off the output of the subsidiary heater 50 (that is, a time for setting the output of the subsidiary heater 50 to be zero (0)). As a result, as shown in FIG. 5C, a peak value of the wire temperature of the subsidiary heater 50 can be set to be lower than a peak value of the wire temperature of the subsidiary heater 50 in the comparative example. In addition, by suppressing the increase in the wire temperature of the subsidiary heater 50, it is possible to suppress the deterioration of the wire of the subsidiary heater 50. In addition, by limiting the time for which the subsidiary heater 50 outputs the heat, it is possible to reduce the power load on the entire heaters.

Alternatively, in the present mode, the controller 200 may maintain (or keep) the output of the subsidiary heater 50 at a constant output equal to or less than the output limit value (which is set in advance). In addition, as long as the increase in the wire temperature of the subsidiary heater 50 is suppressed, the output limit value may not be the same as the output limit value in the first mode.

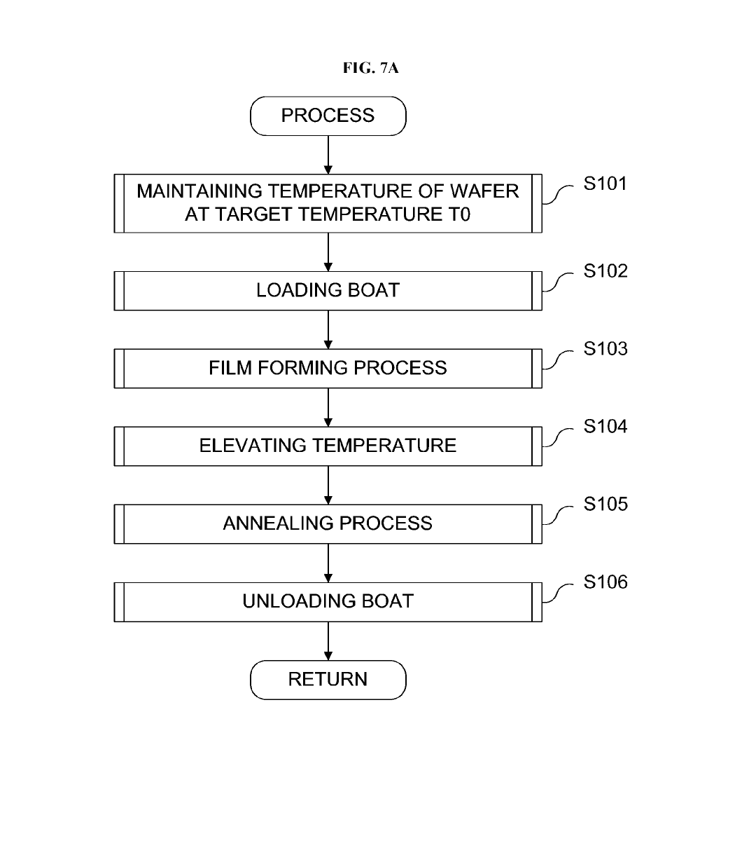

Subsequently, an example of the temperature control according to the embodiments of the present disclosure will be described with reference to a block diagram shown in FIG. 6.

In FIG. 6, the term “TARGET TEMPERATURE” indicates the target temperature T1 in each zone of the heater 14. The target temperature T1 is input to the positive input terminal of a first subtractor.

In FIG. 6, the term “FURNACE TC DETECTION TEMPERATURE” indicates the furnace temperature (that is, the inner temperature of the furnace) measured by the temperature sensor 52 using the thermocouples 303 corresponding to each zone. The furnace temperature detected by the temperature sensor 52 is input to the negative input terminal of the first subtractor. As a result, it is possible to control the furnace temperature to the target temperature T1 corresponding thereto.

The first subtractor calculates a deviation between the target temperature T1 and the furnace temperature, and outputs a result to a first PID calculator.

The first PID calculator receives the deviation from the first subtractor and performs a known PID calculation. A PID calculation result is input to the positive input terminal of a second subtractor.

In FIG. 6, the term “HEATER TC DETECTION TEMPERATURE” indicates the heater temperature measured by the thermocouples 302 corresponding to each zone. The heater temperature detected by the thermocouples 302 corresponding to each zone is input to the negative input terminal of the second subtractor. Alternatively, for a specific zone among the zones, the temperature of the subsidiary heater 50 detected by the thermocouples 304 may be input to the negative input terminal of the second subtractor.

The second subtractor calculates a deviation between a calculation result of the first PID calculator and the heater temperature, and outputs a result to a second PID calculator.

The second PID calculator receives the deviation from the second subtractor and performs a known PID calculation. PID parameters used by the second PID calculator are different from those used by the first PID calculator. The PID calculation result is output as “MANIPULATED VARIABLES.”

It is preferable that the PID parameters (which are used when performing the PID calculations in the first PID calculator and the second PID calculator) are adjustable. The PID parameters are an example of “control parameters for the heating structure” in the technique of the present disclosure. The first PID calculator and the second PID calculator are configured such that the PID parameters can be set appropriately. Similar to the “TARGET TEMPERATURE,” the PID parameters are stored (or recorded) in the controller 200 as a recipe or a table associated with the recipe.

In FIG. 6, the term “MANIPULATED VARIABLES” indicates a value output as a control calculation result corresponding to a zone to be controlled. Such a value is converted into a control signal for heating the zone to be controlled by the heater 14, and the control signal is output. When the output limit value for the subsidiary heater 50 is set as described above, since the maximum value of the “MANIPULATED VARIABLES” is set in advance, the maximum value of the control signal of the subsidiary heater 50 may be limited.

As described above, the controller 200 capable of operating a temperature control system (which performs the temperature control mentioned above) according to the embodiments of the present disclosure is configured to perform control calculations in accordance with a control algorithm known as a cascade control, and further configured to control the furnace temperature to coincide with the target temperature T1 corresponding thereto.

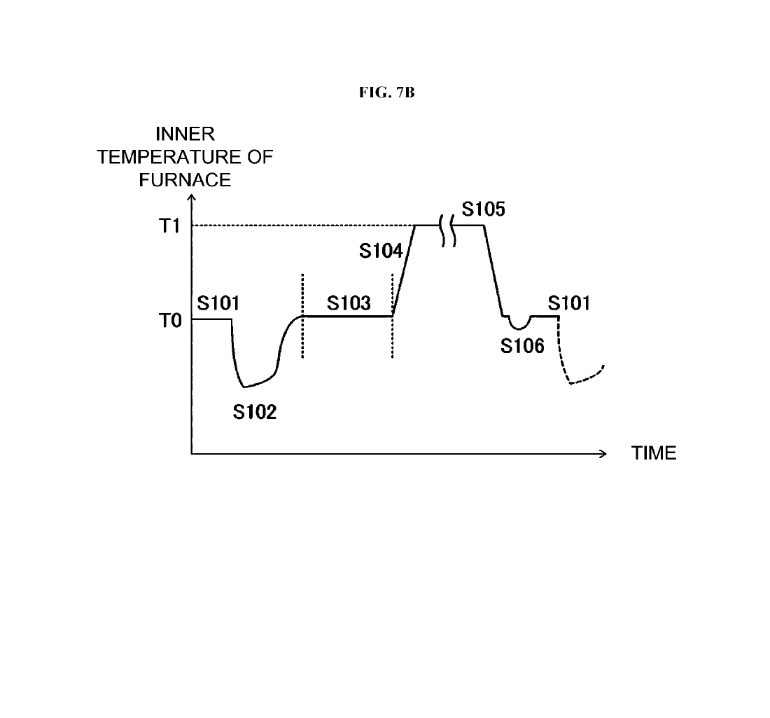

Subsequently, an example of the substrate processing sequence performed by the substrate processing apparatus 10 will be described with reference to FIGS. 7A and 7B.

In a step S101 (standby step), the wafers 2 are maintained at a temperature (standby temperature) in standby before being loaded into the process furnace 12 (or the process chamber 18). For example, according to the present embodiments, the standby temperature is set to be the same as a target temperature T0 serving as a film forming temperature. In the step S101, for example, the wafers 2 may be transferred into the boat 20.

In a step S102 (boat loading step), the wafers 2 are loaded into the process furnace 12 (or the process chamber 18). For example, according to the present embodiments, the wafers 2 are loaded into the process furnace 12 (or the process chamber 18) while accommodated in the boat 20. In such an operation, a temperature of the boat 20 and the temperature of the wafer 2 are lower than the target temperature T0. In addition, as a result of loading the wafers 2 into the process furnace 12 (or the process chamber 18), an atmosphere (outer atmosphere) outside of the process furnace 12 (which is at a room temperature) is introduced into the process furnace 12 (or the process chamber 18). Thereby, the inner temperature of the process furnace 12 (or the process chamber 18) is temporarily decreased below the target temperature T0. After a short period of time, the inner temperature of the furnace is stabilized at the target temperature T0 again under the control of the controller 200. In FIG. 7B, a target temperature after the wafers 2 (that is, the substrates to be processed) are loaded into the process furnace 12 (or the process chamber 18) and the target temperature T0 in a subsequent step (step S103) is shown to be the same as the target temperature T0 in the step S101. However, the target temperature after loading the wafers 2 may differ depending on requirements of the step S103.

In a step S103 (film forming step), the furnace temperature is maintained at the target temperature T0 to perform a predetermined film forming process on the wafers 2.

In a step S104 (temperature elevating step), the furnace temperature is elevated from the target temperature T0 to the annealing temperature at which the annealing process is performed. To perform the annealing process on the wafers 2 on which the film forming process is performed, the controller 200 controls the heater 14 and the subsidiary heater 50 to increase (or elevate) the furnace temperature to the target temperature T1 serving as the annealing temperature (which is higher than the target temperature T0). In such an operation, when the wire temperature of the subsidiary heater 50 detected by the temperature sensor 150 is equal to or higher than the predetermined temperature T2 (which is lower than the target temperature T1), the controller 200 limits the output of the subsidiary heater 50.

In a step S105 (annealing step), the furnace temperature is maintained at the target temperature T1 to perform the annealing process on the wafers 2.

In a step S106 (boat unloading step), the wafers 2 on which the annealing process is performed are unloaded (or taken out) from the process furnace 12 (or the process chamber 18) while accommodated in the boat 20.

When the wafers 2 (which are unprocessed and to be processed) remain, the wafers 2 (which are processed) are unloaded from the boat 20 and replaced with the wafers 2 (which are unprocessed). Then, a series of the steps S101 to S106 is repeatedly performed one or more times.

### Effects

According to the present embodiments, it is possible to obtain one or more effects described below.

By heating the process vessel and each zone unlimitedly using both of the heater 14 and the subsidiary heater 50 up to the predetermined temperature T2 (which is lower than the target temperature T1) and by limiting the output of the subsidiary heater 50 during a process at a temperature higher than the predetermined temperature T2, it is possible to suppress an excessive increase in the wire temperature of the subsidiary heater 50, and it is also possible to reduce the deterioration (wear and tear) of the wire of the subsidiary heater 50. As a result, it is possible to ensure the life of the subsidiary heater 50.

In addition, by heating the process vessel and each zone unlimitedly using both of the heater 14 and the subsidiary heater 50 up to the predetermined temperature T2 (which is lower than the target temperature T1) and by limiting the output of the subsidiary heater 50 during a process at a temperature higher than the predetermined temperature T2, even when the output of the subsidiary heater 50 may exceed the output limit value before the predetermined temperature T2 is reached, it is possible to suppress the excessive increase in the wire temperature of the subsidiary heater 50, and it is also possible to reduce the deterioration (wear and tear) of the wire of the subsidiary heater 50. As a result, it is possible ensure the life of the subsidiary heater 50.

In addition, by limiting the output of the subsidiary heater 50, it is possible to reduce the power load on the entire heaters.

In addition, since the subsidiary heater 50 assists in the heating by the heater 14 corresponding to the specific zone with a large temperature fluctuation, it is possible to improve a temperature uniformity of the wafers 2 (which are arranged in each zone including the specific zone) within surfaces thereof. In addition, it is possible to ensure a temperature uniformity between the zones.

In addition, since the subsidiary heater 50 assists in heating the specific zone, it is possible to elevate the inner temperature of the process vessel corresponding to each zone to the target temperature T1 without delay. For example, the temperature elevation time (the temperature elevating step) is not extended.

In addition, when heating to the target temperature T1, the temperature elevation rate of the subsidiary heater 50 can be set to be lower than the temperature elevation rate of the heater 14. Thereby, it is possible to suppress the excessive increase in the wire temperature of the subsidiary heater 50 during the process at the temperature higher than the predetermined temperature T2, and it is also possible to reduce the deterioration (wear and tear) of the wire of the subsidiary heater 50. As a result, it is possible ensure the life of the subsidiary heater 50.

In addition, when heating to the target temperature T1, the heating by the subsidiary heater 50 can be started later than the heating by the heater 14. Thereby, it is possible to suppress the excessive increase in the wire temperature of the subsidiary heater 50 during the process at the temperature higher than the predetermined temperature T2, and it is also possible to reduce the deterioration (wear and tear) of the wire of the subsidiary heater 50. As a result, it is possible ensure the life of the subsidiary heater 50.

Further, the embodiments and modified examples mentioned above may be appropriately combined. The process procedures and the process conditions of each combination thereof may be substantially the same as those of the embodiments or the modified examples mentioned above. For example, the number of each component described in the present specification is not limited to one, and the number of each component may be two or more unless otherwise specified in the present specification.

### Other Embodiments

The technique of the present disclosure is described in detail by way of the embodiments mentioned above. However, the technique of the present disclosure is not limited thereto. The technique of the present disclosure may be modified in various ways without departing from the scope thereof.

For example, the embodiments mentioned above are described by way of an example in which the technique of the present disclosure is applied when the temperature is elevated (increased) from the film forming process to the annealing process. However, the technique of the present disclosure is not limited thereto. For example, the technique of the present disclosure may be preferably applied when the temperature is elevated simply to perform the film forming process or when the temperature is elevated simply to perform the annealing process.

For example, the embodiments mentioned above are described by way of an example in which a batch type substrate processing apparatus (vertical type substrate processing apparatus) capable of simultaneously processing a plurality of substrates is used to perform a predetermined process. However, the technique of the present disclosure is not limited thereto. For example, the technique of the present disclosure may be preferably applied when a single wafer type substrate processing apparatus capable of processing one or several substrates at once is used to perform the predetermined process. For example, the embodiments mentioned above are described by way of an example in which a substrate processing apparatus including a hot wall type process furnace is used to perform the predetermined process. However, the technique of the present disclosure is not limited thereto. For example, the technique of the present disclosure may be preferably applied when a substrate processing apparatus including a cold wall type process furnace is used to perform the predetermined process.

The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

For example, the substrate processing apparatus according to the technique of the present disclosure may be applied to not only a semiconductor manufacturing apparatus capable of manufacturing the semiconductor device but also an apparatus capable of processing a glass substrate, such as an LCD (Liquid Crystal Display) apparatus. For example, the technique of the present disclosure may also be applied to other substrate processing such as a process of forming a film (such as a CVD (Chemical Vapor Deposition) film, a PVD (Physical Vapor Deposition) film, an oxide film and a nitride film), a process of forming a metal-containing film, an annealing process, an oxidation process, a nitridation process and a diffusion process. In addition, the technique of the present disclosure may also be applied to other substrate processing apparatuses such as an exposure apparatus, a coating apparatus, a drying apparatus and a heating apparatus.

According to some embodiments of the present disclosure, it is possible to suppress the increase in the wire temperature of the auxiliary heater and to ensure the life of the auxiliary heater.

What is claimed is:

1. A temperature control system comprising:
a first heater divided into a plurality of zones and configured to heat a process vessel in which a substrate is arranged;
a second heater configured to assist in heating a specific zone among the plurality of zones by the first heater;
a temperature sensor configured to detect a temperature of the second heater; and
a controller configured to be capable of controlling an inner temperature of the process vessel to a target temperature by limiting an output of the second heater when the temperature detected by the temperature sensor is equal to or higher than a predetermined temperature lower than the target temperature.

2. The temperature control system of claim 1, wherein the controller is configured to be capable of, when the temperature detected by the temperature sensor reaches the predetermined temperature, adjusting the output of the second heater to be lower than or equal to an output limit value in a case where the output of the second heater exceeds the output limit value set in advance.

3. The temperature control system of claim 1, wherein the controller is configured to be capable of, when the temperature detected by the temperature sensor reaches the predetermined temperature, adjusting the output of the second heater from 0 or more to an output equal to or less than an output limit value set in advance until the inner temperature of the process vessel reaches the target temperature.

4. The temperature control system of claim 3, wherein the controller is configured to be capable of, when the temperature detected by the temperature sensor reaches the predetermined temperature, adjusting the output of the second heater in a pulsed manner between a zero output and a pre-set output greater than 0 and equal to or less than the output limit value until the inner temperature of the process vessel reaches the target temperature.

5. The temperature control system of claim 1, wherein the controller is configured to be capable of, when the temperature detected by the temperature sensor reaches the predetermined temperature, keeping the output of the second heater constant at a pre-set output equal to or greater than 0 and equal to or less than an output limit value set in advance until the inner temperature of the process vessel reaches the target temperature.

6. The temperature control system of claim 5, wherein the controller is configured to be capable of, when the temperature detected by the temperature sensor reaches the predetermined temperature, setting the output of the second heater to 0 until the inner temperature of the process vessel reaches the target temperature.

7. The temperature control system of claim 1, wherein the controller is configured to be capable of, when the temperature detected by the temperature sensor reaches the predetermined temperature, adjusting the output of the second heater at or below an output level, at which the predetermined temperature is reached, until the inner temperature of the process vessel detected by the temperature sensor reaches the target temperature in a case where the output of the second heater is equal to or less than an output limit value set in advance.

8. The temperature control system of claim 1, wherein the controller is configured to be capable of, when the temperature detected by the temperature sensor is equal to or higher than the predetermined temperature, heating the process vessel using both of the first heater and the second heater as long as the output of the second heater is equal to or lower than an output limit value set in advance.

9. The temperature control system of claim 1, wherein the controller is configured to be capable of keeping the output of the second heater constant until the temperature detected by the temperature sensor reaches the predetermined temperature.

10. The temperature control system of claim 1, wherein the controller is configured to be capable of controlling the inner temperature of the process vessel facing each of the plurality of zones to reach the target temperature by combining: (i) heating by both of the first heater and the second heater; and (ii) heating by the first heater alone.

11. The temperature control system of claim 10, wherein the controller is configured to be capable of controlling the output of the second heater to be started after an output of the first heater is started.

12. The temperature control system of claim 11, wherein the controller is configured to be capable of, when the temperature detected by the temperature sensor reaches the predetermined temperature, starting the output of the second heater.

13. The temperature control system of claim 12, wherein the controller is configured to be capable of adjusting the output of the second heater to an output level equal to or less than an output limit value set in advance.

14. The temperature control system of claim 12, wherein the controller is configured to be capable of keeping the output of the second heater at a constant output equal to or less than an output limit value set in advance.

15. The temperature control system of claim 1, wherein the controller is configured to be capable of setting a temperature elevation rate of the second heater to be lower than a temperature elevation rate of the first heater.

16. The temperature control system of claim 15, wherein the target temperature is set to be higher than a temperature at which the second heater is capable of being controlled.

17. The temperature control system of claim 1, further comprising:
a first temperature sensor configured to detect the inner temperature of the process vessel,
wherein the specific zone among the plurality of zones is a zone in which a fluctuation in a temperature detected by the first temperature sensor is the largest.

18. A temperature control method comprising:
setting the inner temperature of the process vessel to the target temperature using the temperature control system of claim 1.

19. A method of manufacturing a semiconductor device, comprising:
processing the substrate while maintaining the inner temperature of the process vessel at the target temperature using the temperature control method of claim 18.

20. A substrate processing apparatus comprising:
a first heater divided into a plurality of zones and configured to heat a process vessel in which a substrate is arranged;
a second heater configured to assist in heating a specific zone among the plurality of zones by the first heater;
a temperature sensor configured to detect a temperature of the second heater; and
a controller configured to be capable of controlling an inner temperature of the process vessel to a target temperature by limiting an output of the second heater when the temperature detected by the temperature sensor is equal to or higher than a predetermined temperature lower than the target temperature.
